(19) United States
(12) Patent Application Publication
(10) Pub. No.: US 2026/0082855 A1
(43) Pub. Date: Mar. 19, 2026

(54) SUBSTRATE HOUSING CONTAINER AND REAR RETAINER

(71) Applicant: MIRAIAL CO., LTD., Tokyo (JP)

(72) Inventors: Kouji KUBOTA, Tokyo (JP); Kouichi NISHIZAKA, Tokyo (JP)

(21) Appl. No.: 18/878,482

(22) PCT Filed: Jun. 24, 2022
(86) PCT No.: PCT/JP2022/025312

§ 371 Date: Dec. 23, 2024

(51) Int. Cl. H01L 21/673

(52) U.S. Cl. CPC H10P 72/1924; H10P 72/1921

(57) ABSTRACT

The rear retainer comprises: a rear-side substrate support portion which is disposed to be paired with the lid-side substrate support portion in the substrate housing space and is capable of supporting the edges of substrates, and which, when the container body opening portion is closed by the lid, cooperates with the lid-side substrate support portion to support the substrates with the edges of the substrates arranged in parallel; a protruding wall portion with an outer surface protruding toward the container body opening portion and an inner surface recessed toward the container body opening portion, the protruding wall portion having the rear-side substrate support portion provided on the protruding side of the protruding wall portion; and a circulation hole which, when the protruding side of the protruding wall portion is facing downward, allows circulation of a liquid and/or a gas that is positioned on the inner surface side of the protruding wall portion.

### TECHNICAL FIELD

The present invention relates to a substrate storing container and a rear retainer that are used in, for example, storing, keeping, conveying, transporting, and the like substrates composed of semiconductor wafers or the like.

### BACKGROUND ART

A known substrate storing container for storing and conveying substrates composed of semiconductor wafers includes a container body and a lid.

The container body includes a tubular wall having a container body opening formed at one end thereof and having the other end closed. The container body has a substrate storing space formed therein. The substrate storing space is surrounded and defined by the wall and can store a plurality of substrates. The lid is detachably attachable to the container body opening and can close the container body opening.

A front retainer is provided on a part of the lid that faces the substrate storing space when the container body opening is closed by the lid. The front retainer can support edge portions of the plurality of substrates in a state where the container body opening is closed by the lid. Furthermore, a rear retainer is provided on a wall-side of the substrate storing space of the container body so as to form a counterpart to the front retainer. The rear retainer can support edge portions of the plurality of substrates. When the container body opening is closed by the lid, the rear retainer cooperates with the front retainer to support and hold the plurality of substrates such that the adjacent substrates are arranged in parallel and spaced apart from each other by a predetermined interval.

### CITATION LIST

### Patent Document

Patent Document 1: Japanese U.S. Pat. No. 4,459,015

### DISCLOSURE OF THE INVENTION

### Problems to be Solved by the Invention

There is a case where the substrate storing container is cleaned in a state where the rear retainer is disposed adjacent to a back wall of the substrate storing space of the container body. (The rear retainer may be of a type that is detachably attached, or a type that is integrated with the container body by insert molding or the like.) In the case of such cleaning, there is a problem that a cleaning liquid (including water) existing on an inner surface side of the rear retainer (a surface facing the back wall of the container body) is hard to drain from (or likely to remain on) the inner surface side of the rear retainer. Furthermore, there is another problem of poor breathability (ventilation) between an inner surface side and an outer surface side of the rear retainer. If the cleaning liquid is hard to drain or the breathability is poor, there is a concern that the inner surface side of the rear retainer is insufficiently dried after cleaning, which needs to be addressed by, for example, increasing time for drying. As a result, the time required for a drying step becomes unnecessarily long, and the manufacture cost increases accordingly.

It is an object of the present invention to provide a substrate storing container and a rear retainer that can solve or alleviate the problem of insufficient drying of the inner surface side of the rear retainer after cleaning, in a case where the substrate storing container is cleaned while having the rear retainer disposed adjacent to a back wall of the substrate storing space of the container body.

Means for Solving the Problems The present invention relates to a substrate storing container including: a container body including a tubular wall that has one end at which a container body opening is formed and another end closed, the container body having a substrate storing space defined by an inner surface of the tubular wall, the substrate storing space being capable of storing a plurality of substrates and communicating with the container body opening; a lid detachably attachable to the container body opening and capable of closing the container body opening; lid-side substrate supports disposed on a portion of the lid, the portion facing the substrate storing space when the container body opening is closed by the lid, the lid-side substrate supports being capable of supporting edge portions of the plurality of substrates when the container body opening is closed by the lid; and a rear retainer, wherein the rear retainer includes: back-side substrate supports disposed in the substrate storing space so as to form counterparts to the lid-side substrate supports and capable of supporting the edge portions of the plurality of substrates, the back-side substrate supports being configured to support the plurality of substrates in collaboration with the lid-side substrate supports such that the edge portions of the plurality of substrates are arranged in parallel with each other when the container body opening is closed by the lid; a protruding wall having an outer surface that protrudes toward the container body opening and an inner surface that is concave toward the container body opening, wherein the back-side substrate supports are provided on a protruding side of the protruding wall; and flow holes through which liquid and/or gas existing on a side of the inner surface of the protruding wall flows when the protruding side of the protruding wall faces downward.

It may be preferable that the flow holes extend in an upward/downward direction to penetrate the back-side substrate supports, in a state in which the protruding side of the protruding wall faces downward.

It may be preferable that the rear retainer is fixed to the container body with a gap between the rear retainer and a back wall of the tubular wall of the container body.

It may be preferable that the back-side substrate supports have: V-shaped grooves each of which is formed of a lower inclined face disposed on a lower side and an upper inclined face disposed on an upper side in a state in which the container body opening faces sideways; and a rib that protrudes upward and extends in a direction from the container body opening toward the back wall of the tubular wall is provided on a laterally inner side of the lower inclined face, in the state in which the container body opening faces sideways.

It may be preferable that the rear retainer further includes: auxiliary grooves which are disposed on a portion that faces the substrate storing space when the container body opening is closed by the lid, the auxiliary grooves each having an opening that is greater than a thickness of an edge portion of a substrate to allow insertion of the edge portion of the substrate; the auxiliary grooves are each formed of groove forming surfaces that are opposite to each other and the edge portions of the plurality of substrates are inserted into the auxiliary grooves on a one-to-one basis at least when the container body opening is closed by the lid; when the container body opening is closed by the lid, the edge portions of the substrates are inserted into the auxiliary grooves in a non-contact state in which an edge portion of each substrate is not in contact with the groove forming surfaces and a space is formed between the edge portion and each of the groove forming surfaces; and in the state in which the container body opening faces sideways, the groove forming surfaces of each auxiliary groove are located between the V-shaped grooves of the back-side substrate supports adjacent to each other in an upward/downward direction.

It may be preferable that a rib that protrudes in an upward direction and extends in a direction from the container body opening toward the back wall of the tubular wall is provided on a laterally inner side of a groove forming surface located under an auxiliary groove, in the state in which the container body opening faces sideways.

The present invention further relates to a rear retainer for use in a substrate storing container that includes: a container body including a tubular wall that has one end at which a container body opening is formed and another end closed, the container body having a substrate storing space defined by an inner surface of the tubular wall, the substrate storing space being capable of storing a plurality of substrates and communicating with the container body opening; a lid detachably attachable to the container body opening and capable of closing the container body opening; and lid-side substrate supports disposed on a portion of the lid, the portion facing the substrate storing space when the container body opening is closed by the lid, the lid-side substrate supports being capable of supporting edge portions of the plurality of substrates when the container body opening is closed by the lid. The rear retainer includes: back-side substrate supports disposed in the substrate storing space so as to form counterparts to the lid-side substrate supports and capable of supporting the edge portions of the plurality of substrates, the back-side substrate supports being configured to support the plurality of substrates in collaboration with the lid-side substrate supports such that the edge portions of the plurality of substrates are arranged in parallel with each other when the container body opening is closed by the lid; a protruding wall having an outer surface that protrudes toward the container body opening and an inner surface that is concave toward the container body opening, wherein the back-side substrate supports are provided on a protruding side of the protruding wall; and flow holes through which liquid and/or gas existing on a side of the inner surface of the protruding wall flows when the protruding side of the protruding wall faces downward.

### Effects of the Invention

It is possible for the present invention to provide a substrate storing container and a rear retainer that can solve or alleviate the problem of insufficient drying of the inner surface side of the rear retainer after cleaning in a case where the substrate storing container is cleaned while having the rear retainer disposed adjacent to the back wall in the substrate storing space of the container body.

### BRIEF DESCRIPTION OF THE DRAWINGS

FIG. 1 is an exploded perspective view illustrating a state in which a plurality of substrates W are stored in a substrate storing container 1 according to an embodiment of the present invention;

FIG. 2 is a perspective view illustrating a container body 2 of the substrate storing container 1 according to the embodiment of the present invention;

FIG. 3 is a perspective view illustrating a lid 3 of the substrate storing container 1 according to the embodiment of the present invention;

FIG. 4 is a plan view of a cross section illustrating a positional relationship between the substrate storing container 1 and the substrate W in a lid closed state;

FIG. 5A is a perspective view illustrating a front retainer 7 of the substrate storing container 1 according to the embodiment of the present invention;

FIG. 5B is a partial front view illustrating the front retainer 7 of the substrate storing container 1 according to the embodiment of the present invention;

FIG. 5C is a longitudinal cross-sectional view schematically illustrating a lid-side substrate support 73 of the front retainer 7;

FIG. 5D is a longitudinal cross-sectional view schematically illustrating a substrate edge portion auxiliary portion 75 of the front retainer 7;

FIG. 6A is a perspective view illustrating a rear retainer 6 of the substrate storing container 1 according to the embodiment of the present invention;

FIG. 6B is a partial front view illustrating the rear retainer 6 of the substrate storing container 1 according to the embodiment of the present invention;

FIG. 7A is a partial enlarged view illustrating a periphery of a protruding wall 60 as shown on the left side in FIG. 6A;

FIG. 7B is a partial enlarged view illustrating a periphery of the protruding wall 60 as shown on the Left Side in FIG. 6b;

FIG. 7C is a longitudinal cross-sectional view schematically illustrating a back-side substrate support 63 and a substrate edge portion auxiliary portion 65 of the rear retainer 6;

FIG. 8 is a partial enlarged view illustrating a periphery of the protruding wall 60 as shown on the left side in FIG. 4; and

FIG. 9 is a cross-sectional view taken along line A-A in FIG. 6B.

### PREFERRED MODE FOR CARRYING OUT THE INVENTION

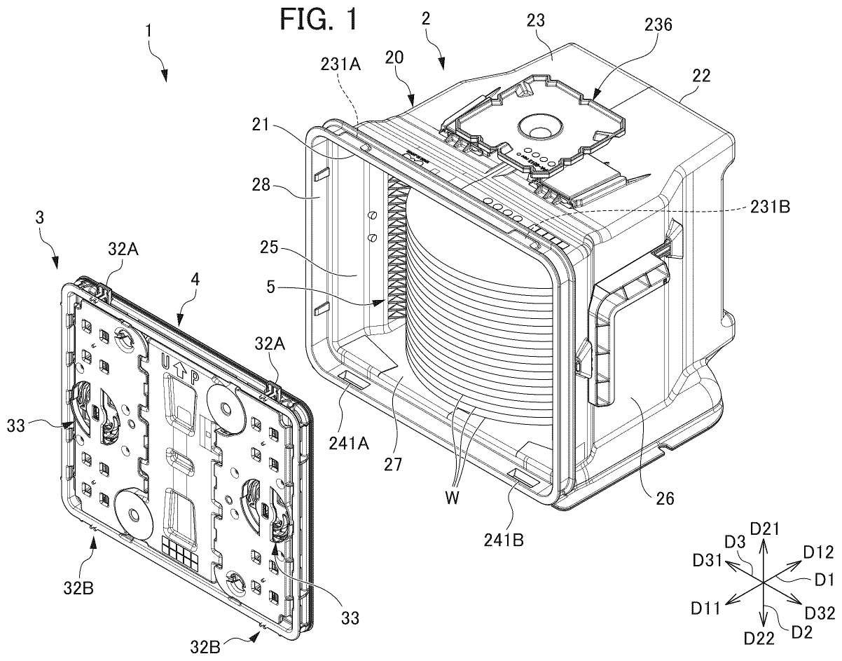

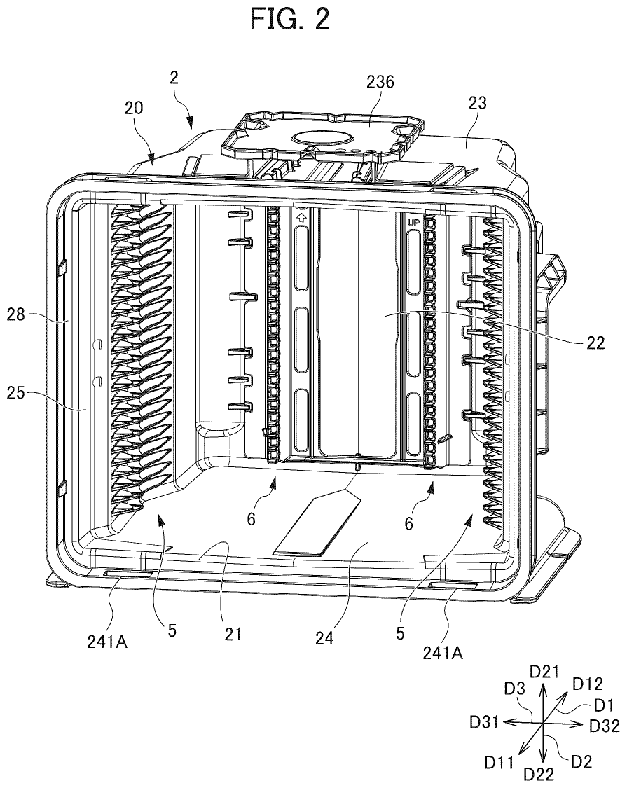

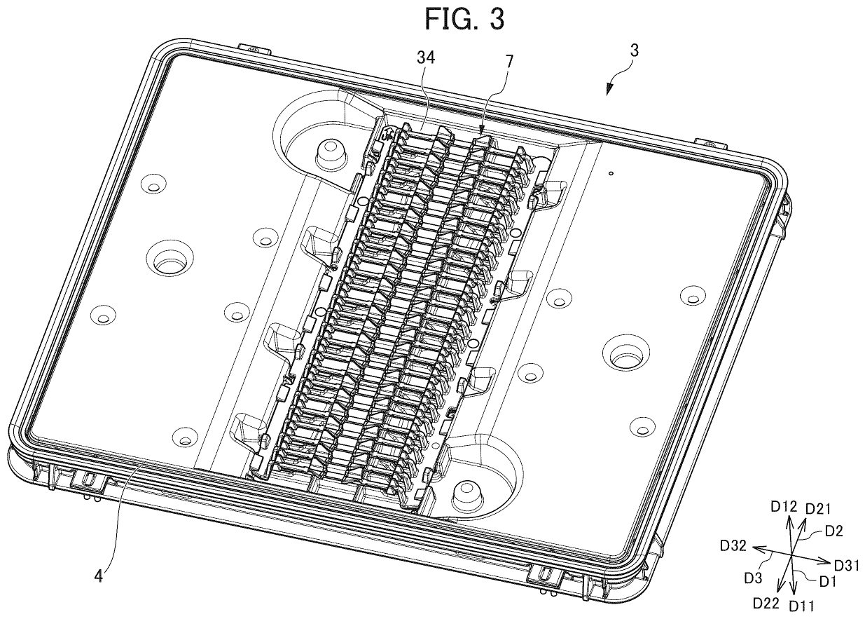

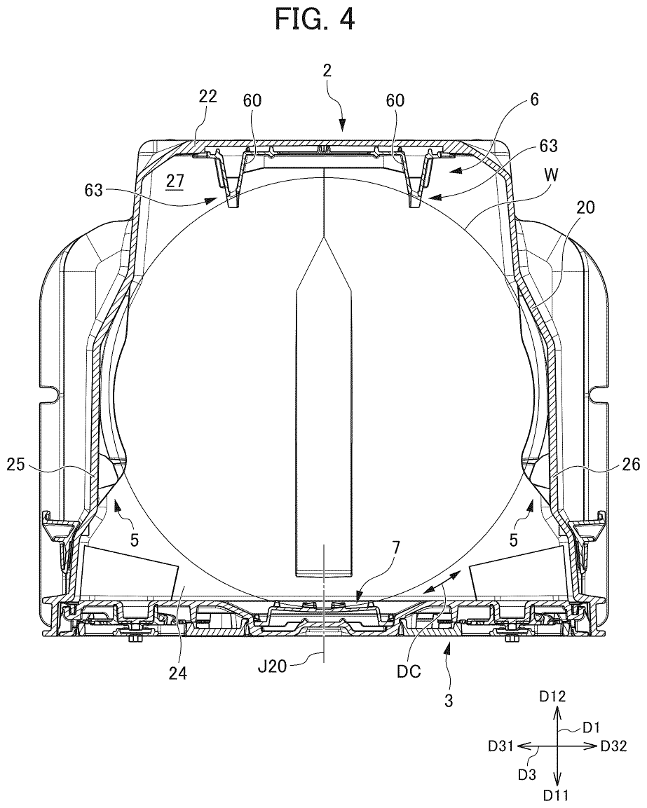

A substrate storing container 1 according to an embodiment will be described below with reference to the drawings. FIG. 1 is an exploded perspective view illustrating a state in which a plurality of substrates W are stored in the substrate storing container 1 according to an embodiment of the present invention. FIG. 2 is a perspective view illustrating a container body 2 of the substrate storing container 1 according to the embodiment of the present invention. FIG. 3 is a perspective view illustrating a lid 3 of the substrate storing container 1 according to the embodiment of the present invention. FIG. 4 is a plan view of a cross section illustrating a positional relationship between the substrate storing container 1 and the substrate W in a lid closed state.

Here, for the sake of convenience of description, a direction from the container body 2 (to be described later) toward the lid 3 (to be described later) (i.e., a direction from the upper right to the lower left in FIG. 1) is defined as a forward direction D11 or a front side D11, a direction opposite thereto is defined as a backward direction D12 or a back side D12, and the forward and backward directions are collectively defined as a forward/backward direction D1. A direction from a lower wall 24 (to be described later) toward an upper wall 23 (to be described later)(i.e., an upward direction in FIG. 1) is defined as an upward direction D21 or an upper side D21, a direction opposite thereto is defined as a downward direction D22 or a lower side D22, and the upward and downward directions are collectively defined as an upward/downward direction D2. A direction from a second side wall 26 (to be described later) toward a first side wall 25 (to be described later) (i.e., a direction from the lower right to the upper left in FIG. 1) is defined as a left direction D31, a direction opposite thereto is defined as a right direction D32, and the left and right directions are collectively defined as a left/right direction D3 or a lateral direction D3. Some of the drawings show arrows indicating the foregoing directions.

Substrates W stored in the substrate storing container 1 (see FIG. 1) include industrially used thin substrates such as disk-shaped silicon wafers, disk-shaped glass wafers, and disk-shaped sapphire wafers. The substrate W of the present embodiment is a silicon wafer having a diameter of 300 mm.

As illustrated in FIGS. 1 and 2, the substrate storing container 1 in which the substrates W of silicon wafers are stored is used as a shipping container for transporting the substrates W through transportation means such as land, air, and sea transportation. The substrate storing container 1 includes a container body 2 and a lid 3. The container body 2 includes substrate support plate-like portions 5 as lateral substrate supports, and a rear retainer 6. The lid 3 includes a front retainer 7 (see FIGS. 3 to 5D) having lid-side substrate supports 73 and substrate edge portion auxiliary portions 75.

As illustrated in FIG. 1, etc., the container body 2 includes a tubular wall 20 that has one end at which a container body opening 21 is formed and the other end closed. The container body 2 has a substrate storing space 27 formed therein. The substrate storing space 27 is surrounded and defined by the wall 20. As illustrated in FIG. 2, the substrate support plate-like portions 5 are disposed on portions of the wall 20 that define the substrate storing space 27. As illustrated in FIG. 1, the plurality of substrates W can be stored in the substrate storing space 27.

The substrate support plate-like portions 5 are provided on the wall 20 so as to form counterparts to each other in the substrate storing space 27. When the container body opening 21 is not closed by the lid 3 (in a lid open state), the substrate support plate-like portions 5 can support edge portions of the plurality of substrates W by contacting with the edge portions of the plurality of substrates W such that adjacent substrates W are arranged in parallel and spaced apart from each other by a predetermined interval. The rear retainer 6 is provided on a back wall 22 (to be described later) of the wall 20 of the container body 2.

As illustrated in FIG. 4, the rear retainer 6 (see FIG. 2, etc.) is provided on the wall 20 such that the rear retainer 6 forms a counterpart to the front retainer 7 (to be described later) in the substrate storing space 27. When the container body opening 21 is closed by the lid 3 (in a lid closed state), the rear retainer 6 can support rear edge portions of the plurality of substrates W by contacting with the rear edge portions of the plurality of substrates W.

The lid 3 is detachably attachable to an opening peripheral edge 28 (FIG. 1, etc.) that defines the container body opening 21, and can close the container body opening 21. The front retainer 7 is provided on a portion of the lid 3 that faces the substrate storing space 27 when the container body opening 21 is closed by the lid 3. The front retainer 7 is disposed so as to form a counterpart to the rear retainer 6 in the substrate storing space 27.

As illustrated in FIG. 4, when the container body opening 21 is closed by the lid 3, the front retainer 7 can support front edge portions of the plurality of substrates W by contacting with the front edge portions of the plurality of substrates W. When the container body opening 21 is closed by the lid 3, the front retainer 7 holds the plurality of substrates W in collaboration with the rear retainer 6 such that the adjacent substrates W are arranged in parallel and spaced apart from each other by a predetermined interval.

The substrate storing container 1 is made of a resin such as a plastic material, and examples of the resin include thermoplastic resins such as polycarbonate, cycloolefin polymer, polyetherimide, polyetherketone, polybutylene terephthalate, polyetheretherketone, and liquid crystal polymer, and alloys thereof. An electrically conductive substance, such as carbon fibers, carbon powder, carbon nanotubes, an electrically conductive polymer, and the like, is selectively added to the foregoing resins of molding material in a case where electrical conductivity is to be imparted. It may also be possible to add glass fibers, carbon fibers, or the like to increase the rigidity.

In the following, each of the components will be described in detail. As illustrated in FIG. 1, the wall 20 of the container body 2 includes the back wall 22, the upper wall 23, the lower wall 24, the first side wall 25, and the second side wall 26. The back wall 22, the upper wall 23, the lower wall 24, the first side wall 25, and the second side wall 26, which are each made of one or more of the above-described materials, are formed by integral molding.

The first side wall 25 is opposite to the second side wall 26, and the upper wall 23 is opposite to the lower wall 24. A back end of the upper wall 23, back end of the lower wall 24, back end of the first side wall 25, and back end of the second side wall 26 are all connected to the back wall 22. A front end of the upper wall 23, front end of the lower wall 24, front end of the first side wall 25, and front end of the second side wall 26, which are each opposite to the back wall 22, constitute the opening peripheral edge 28 that defines the container body opening 21 having a substantially rectangular shape.

The opening peripheral edge 28 is provided at one end of the container body 2, and the back wall 22 is located at the other end of the container body 2. The external outline of the container body 2 which is formed with outer surfaces of the wall 20 is shaped like a box. An inner surface of the wall 20, that is, an inner surface of the back wall 22, inner surface of the upper wall 23, inner surface of the lower wall 24, inner surface of the first side wall 25, and inner surface of the second side wall 26 surround and define the substrate storing space 27. The container body opening 21 defined by the opening peripheral edge 28 communicates with the substrate storing space 27 surrounded by the wall 20 and formed in the container body 2. A maximum of twenty-five substrates W can be stored in the substrate storing space 27.

As illustrated in FIG. 1, latch engagement recesses 231A, 231B, 241A, and 241B, which are recessed outward with respect to the substrate storing space 27, are formed in portions of the upper wall 23 and the lower wall 24 near the opening peripheral edge 28. A total of four latch engagement recesses 231A, 231B, 241A, and 241B are formed in proximity to the left and right ends of the upper wall 23 and the left and right ends of the lower wall 24, on a one-to-one basis.

As illustrated in FIG. 1, a top flange 236 is fixed to a central portion of the upper wall 23. The top flange 236 is a member with which the substrate storing container 1 is hooked and hung, when used in an automated wafer transport system (e.g., an AMHS), a wafer substrate transport cart (e.g., a PGV), or the like.

The substrate support plate-like portions 5, which are provided integrally with the first side wall 25 and the second side wall 26, respectively, are arranged so as to form counterparts to each other in the left/right direction D3. The substrate support plate-like portions 5 may each be a separate component from the first side wall 25 and the second side wall 26.

The substrate support plate-like portions 5 each have a substantially arc shape of a plate. Twenty-five substrate support plate-like portions 5 are provided in the upward/downward direction D2 on each of the first side wall 25 and the second side wall 26, amounting to fifty. An adjacent pair of the substrate support plate-like portions 5 is arranged in parallel with and spaced apart from each other by an interval of 10 mm to 12 mm in the upward/downward direction D2. Another plate-like member is disposed above and in parallel with the uppermost substrate support plate-like portion 5. This member serves as a guide when the uppermost substrate W is inserted into the substrate storing space 27.

The twenty-five substrate support plate-like portions 5 on the first side wall 25 and the twenty-five substrate support plate-like portions 5 on the second side wall 26 are positioned to be opposite to each other in the left/right direction D3. The 50 substrate support plate-like portions 5 and plate-like members, which are parallel to the substrate support plate-like portions 5 and serve as guides, are parallel to the inner surface of the lower wall 24. As illustrated in FIG. 2, etc., each substrate support plate-like portion 5 has a protrusion on its upper surface. The substrate W supported on the substrate support plate-like portion 5 contacts with only the protruding end of the protrusion, and is not in plane contact with the substrate support plate-like portion 5.

The substrate support plate-like portions 5 are capable of supporting edge portions of the plurality of substrates W in a state in which an adjacent pair of the plurality of substrates W is spaced apart from each other by a predetermined interval and in parallel with each other.

The rear retainer 6 is an interior component fixed (attached) to the back wall 22 of the container body 2 and disposed in the substrate storing space 27. Details of the rear retainer 6 will be described later. Instead of attaching the rear retainer 6 to the container body 2, the rear retainer 6 and the container body 2 may be integrally formed by insert molding or the like, so that the rear retainer 6 is on the back wall 22 of the container body 2.

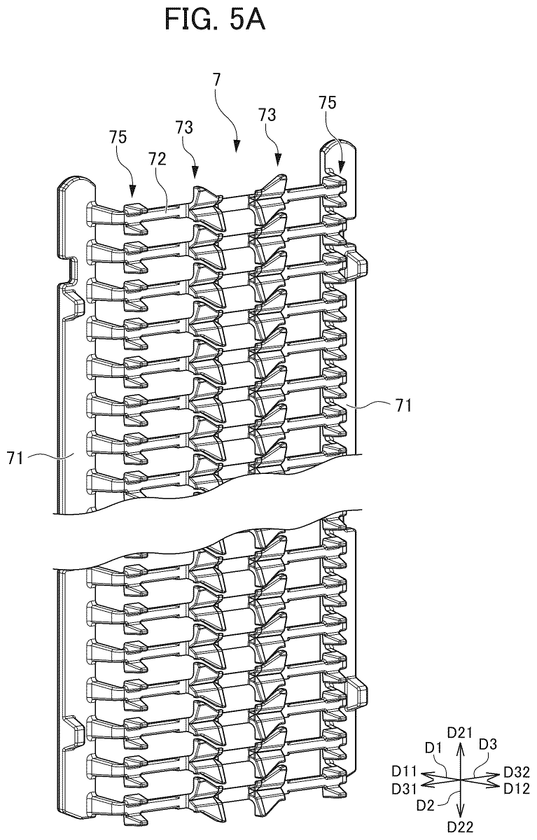

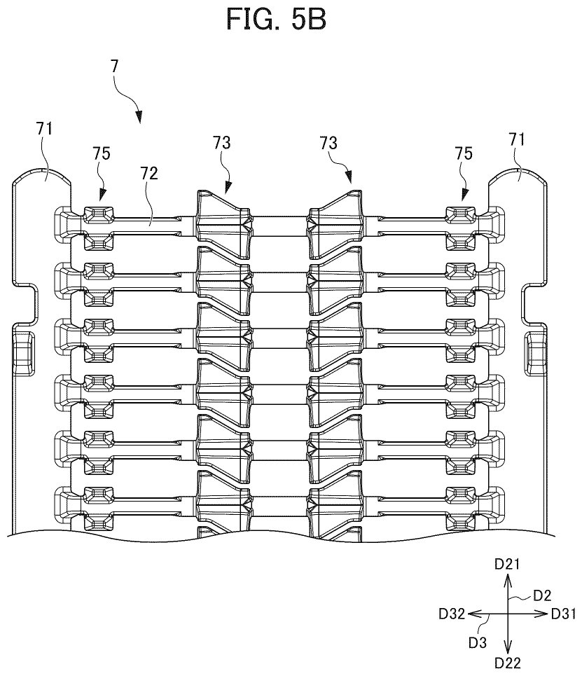

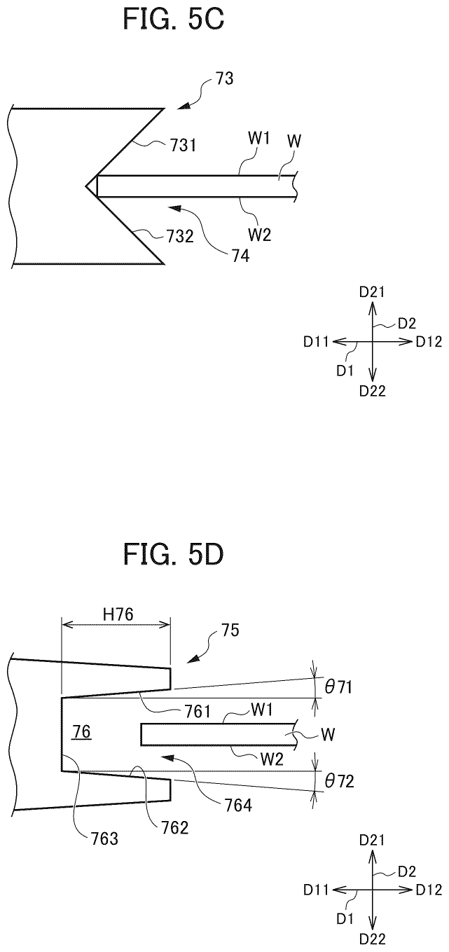

Next, the lid 3 and the front retainer 7 will be described in detail. FIG. 5A is a perspective view illustrating the front retainer 7 of the substrate storing container 1 according to the embodiment of the present invention. FIG. 5B is a partial front view illustrating the front retainer 7 of the substrate storing container 1 according to the embodiment of the present invention. FIG. 5C is a longitudinal cross-sectional view schematically illustrating a lid-side substrate support 73 of the front retainer 7. FIG. 5D is a longitudinal cross-sectional view schematically illustrating a substrate edge portion auxiliary portion 75 of the front retainer 7.

As illustrated in FIG. 1, the lid 3 has a substantially rectangular shape that substantially coincides with the opening peripheral edge 28 of the container body 2. The lid 3 is detachably attachable to the opening peripheral edge 28 of the container body 2. When attached to the opening peripheral edge 28, the lid 3 can close the container body opening 21. An annular sealing member 4 is attached to the inner surface of the lid 3 (the surface on the back side of the lid 3 in FIG. 1). Examples of material for the sealing member 4 include various thermoplastic elastomers such as polyester-based elastically deformable elastomers and polyolefin-based elastically deformable elastomers, fluorine rubber, silicon rubber, etc. The sealing member 4 is arranged to extend annularly along the entire peripheral edge of the lid 3.

In a state where the lid 3 is attached to the opening peripheral edge 28, the sealing member 4 is sandwiched between the opening peripheral edge 28 and the inner surface of the lid 3 to deform elastically, whereby the lid 3 hermitically closes the container body opening 21. By detaching the lid 3 from the opening peripheral edge 28, the substrates W can be placed into and removed from the substrate storing space 27 in the container body 2.

The lid 3 has a lid body that forms the external outline of the lid 3 and that is provided with a latch mechanism. As illustrated in FIG. 1, the latch mechanism is provided in proximity to the left and right ends of the lid body, and includes two upper latch parts 32A that can protrude from the upper side of the lid body in the upward direction D21, and two lower latch parts 32B that can protrude from the lower side of the lid body in the downward direction D22. The two upper latch parts 32A are disposed in proximity to the left and right ends of the upper side of the lid body, and the two lower latch parts 32B are disposed in proximity to the left and right ends of the lower side of the lid body.

The outer surface of the lid body is provided with operation parts 33. Handling the operation parts 33 from the front side of the lid body causes the upper latch parts 32A to protrude from the upper side of the lid body and the lower latch parts 32B to protrude from the lower side, or to retract not to protrude. The upper latch parts 32A protrude from the upper side of the lid body in the upward direction D21 to engage with the latch engagement recesses 231A, 231B of the container body 2, and the lower latch parts 32B protrude from the lower side of the lid body in the downward direction D22 to engage with the latch engagement recesses 241A, 241B of the container body 2, whereby the lid 3 is fastened to the opening peripheral edge 28 of the container body 2.

As illustrated in FIG. 3, a recess 34 which is concave outward with respect to the substrate storing space 27 (concave in the forward direction D11) is formed on the inner side of the lid body constituting the lid 3. The front retainer 7 is fixed (attached) to a part of the lid body inside the recess 34.

As illustrated in FIGS. 3, 5A, and 5B, the front retainer 7 includes the lid-side substrate supports 73, the substrate edge portion auxiliary portions 75, legs 72, and vertical frames 71. A lid-side substrate support 73 and a substrate edge portion auxiliary portion 75 that correspond to the same substrate W are connected to each other via a leg 72.

Two lid-side substrate supports 73 are arranged to make a pair, such that they are spaced apart from each other by a predetermined interval in the left/right direction D3. The lid-side substrate supports 73 are arranged in twenty-five pairs in parallel in the upward/downward direction D2, each lid-side substrate support 73 being supported by an elastically deformable leg 72. The legs 72 respectively extend from the lid-side substrate supports 73 arranged in pairs outwardly away from each other in the left/right direction D3, and bend in the forward direction D11. The vertical frames 71, which extend in parallel with each other in the upward/downward direction D2, are integrated with the outer ends of the legs 72 in the left/right direction D3. When the substrates W are stored in the substrate storing space 27 and the lid 3 is closed, the lid-side substrate supports 73 hold and support ends of an edge portion of the substrates W while urging the substrates W toward the center of the substrate storing space 27 with the elastic force of the legs 72.

As illustrated in FIG. 5C, each lid-side substrate support 73 has an upper inclined face 731 and a lower inclined face 732.

The upper inclined face 731 is in contact with an edge end of the front side (upper surface) of a substrate W when the container body opening 21 is closed by the lid 3. The lower inclined face 732 is in contact with an edge end of the back side (lower surface) of the substrate W. Specifically, the upper inclined face 731 is constituted with a surface that slopes toward the center of the substrate storing space 27 in the forward/backward direction D1 as the upper inclined face 731 extends in the upward direction D21. The lower inclined face 732 is constituted by a surface that slopes away from the center of the substrate storing space 27 in the forward/backward direction D1 as the lower inclined face 732 extends in the upward direction D21. The upper inclined face 731 and the lower inclined face 732 form a V-shaped groove 74 that is concave away from the center of the substrate storing space 27.

When the container body opening 21 is closed by the lid 3, an edge end of a front side W1 of the substrate W and an edge end of a back side W2 of the substrate W are in contact with the upper inclined face 731 and the lower inclined face 732, respectively.

The substrate edge portion auxiliary portions 75 are arranged in pairs to be spaced apart from each other by a predetermined interval in the left/right direction D3. The substrate edge portion auxiliary portions 75 are arranged in twenty-five pairs in parallel in the upward/downward direction D2, and each pair is supported by a leg 72. In the present embodiment, each of the substrate edge portion auxiliary portions 75 is disposed between a lid-side substrate support 73 and a vertical frame 71 in the left/right direction D3.

The substrate edge portion auxiliary portions 75 are each disposed on a part of the lid 3 that faces the substrate storing space 27 when the container body opening 21 is closed by the lid 3. As illustrated in FIG. 5D, each of the substrate edge portion auxiliary portions 75 has a groove 76 having an opening that is greater than the thickness of the edge portion of a substrate W to allow insertion of the edge portion of the substrate W. Each auxiliary groove 76 has groove forming surfaces including a front-side facing surface 761, a back-side facing surface 762, and a bottom surface 763.

When the container body opening 21 is closed by the lid 3, the edge portion of the substrate W is inserted into the auxiliary groove 76 in a non-contact state in which the edge portion of the substrate W is not in contact with the groove forming surfaces (the front-side facing surface 761, the back-side facing surface 762, and the bottom surface 763) of the auxiliary groove 76 and a space is formed between the edge portion of the substrate W and each of the groove forming surfaces.

Each auxiliary groove 76 has a substantially rectangular shape in cross-sectional view. Each auxiliary groove 76 has groove forming surfaces opposite to each other (a front-side facing surface 761 and a back-side facing surface 762). At least when the container body opening 21 is closed by the lid 3, edge portions of the plurality of substrates W are inserted into the auxiliary grooves 76 on a one-to-one basis. The auxiliary grooves 76 are disposed more outward in a circumferential direction DC of the edge portion of the substrate W than the lid-side substrate supports 73 with respect to a central axis J20 (see FIG. 4) of the tubular wall 20.

When the container body opening 21 is closed by the lid 3, the front-side facing surface 761 is substantially parallel to the front side W1 of the substrate W, and a part of the front-side facing surface 761 faces the front side W1 in the upward/downward direction D2, which connects the front side W1 and the back side W2. When the container body opening 21 is closed by the lid 3, the back-side facing surface 762 is substantially parallel to the back side W2 of the substrate W, and a part of the back-side facing surface 762 faces the back side W2 in the upward/downward direction D2, which connects the front side W1 and the back side W2. The bottom surface 763 constitutes the bottom of the auxiliary groove 76, and is connected to the front-side facing surface 761 and the back-side facing surface 762.

The front-side facing surface 761 and the back-side facing surface 762 are substantially plane. The front-side facing surface 761 and the back-side facing surface 762 constitute a pair of inclined faces that are slightly inclined so that an opening 764 of the auxiliary groove 76 slightly increases from the bottom of the auxiliary groove 76 toward the opening 764. An angle θ71 formed between the front side W1 of the substrate W and the front-side facing surface 761 and/or an angle θ72 formed between the back side W2 and the back-side facing surface 762 are/is, for example, 30 degrees or less, preferably 15 degrees or less.

Each auxiliary groove 76 has a depth H76. The edge portions of the plurality of substrates W are not inserted into the auxiliary grooves 76 when the container body opening 21 is not closed by the lid 3 and the substrate support plate-like shaped portions 5 serving as lateral substrate supports support edge portions of the plurality of substrates W. On the other hand, the edge portions of the substrates W can be inserted into the auxiliary grooves 76 with the depth H76 when the container body opening 21 is closed by the lid 3. The depth H76 of the auxiliary groove 76 is, for example, 3.5 mm or greater, may preferably be 4.5 mm or greater, and may more preferably be 4.5 mm to 6.0 mm.

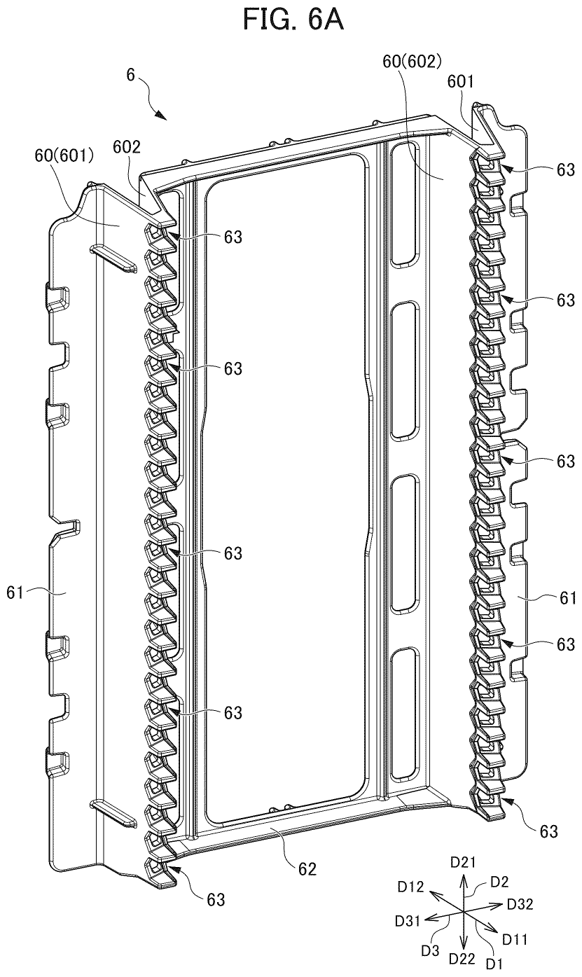

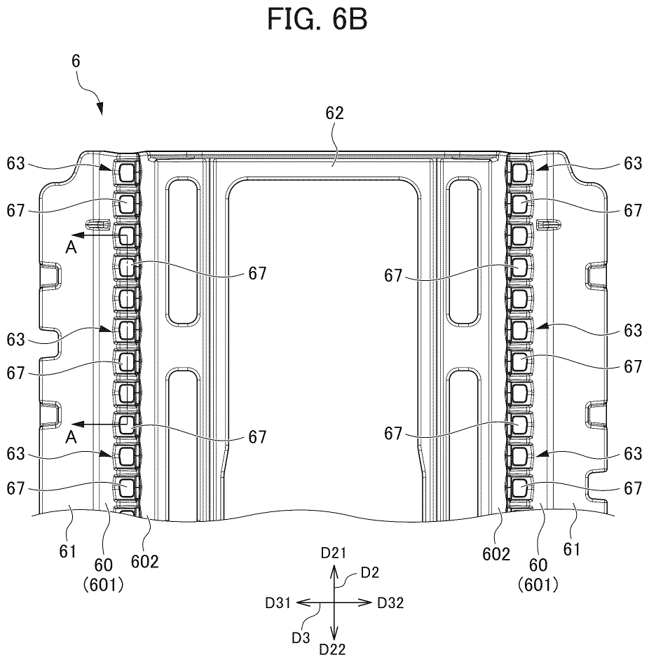

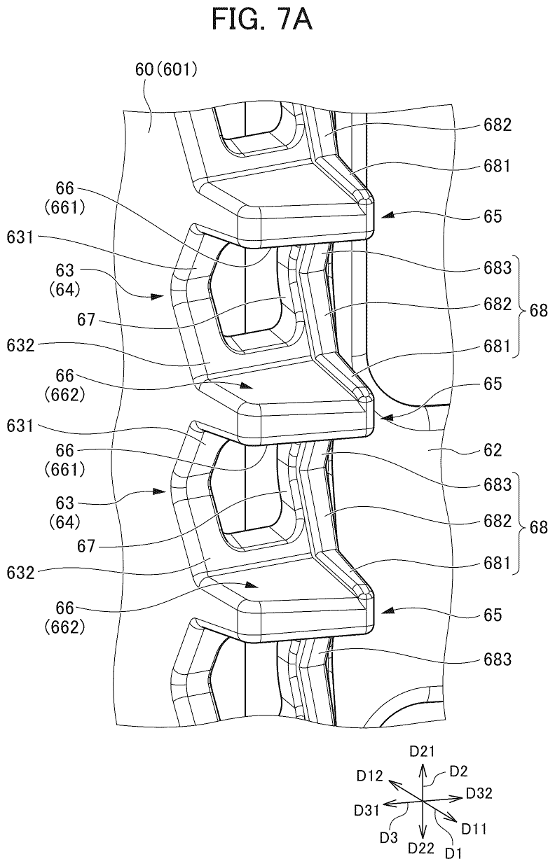

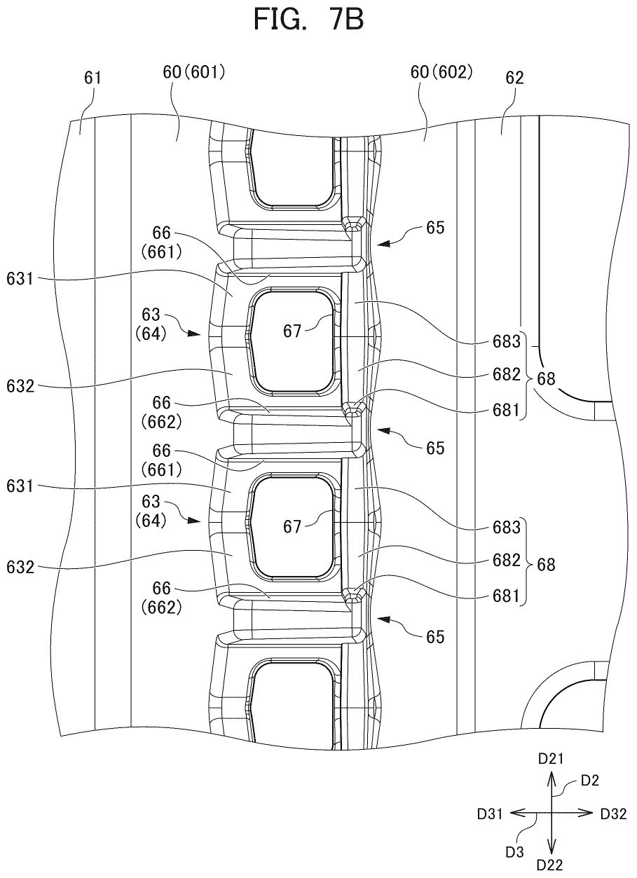

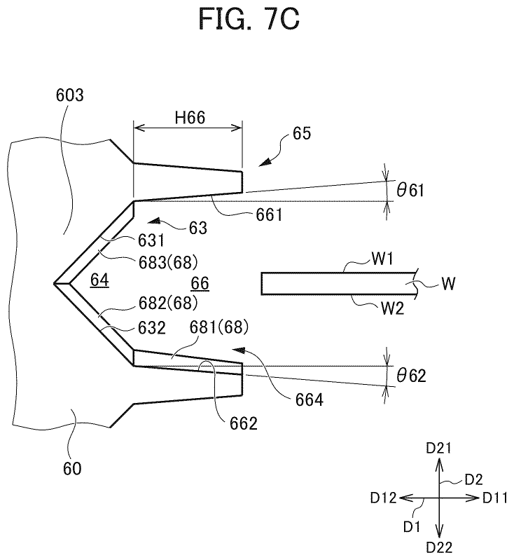

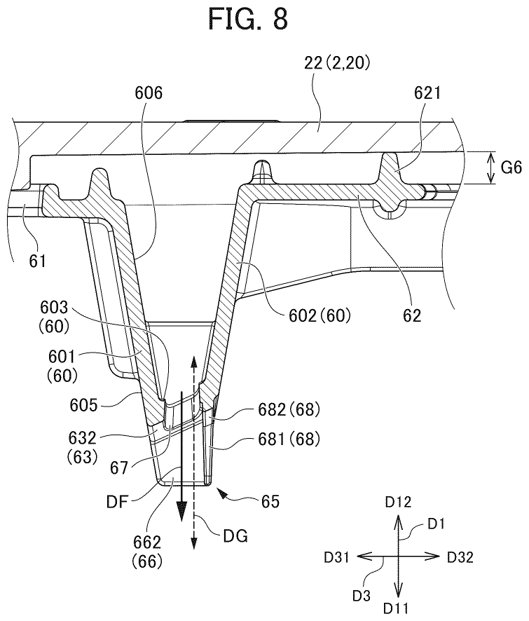

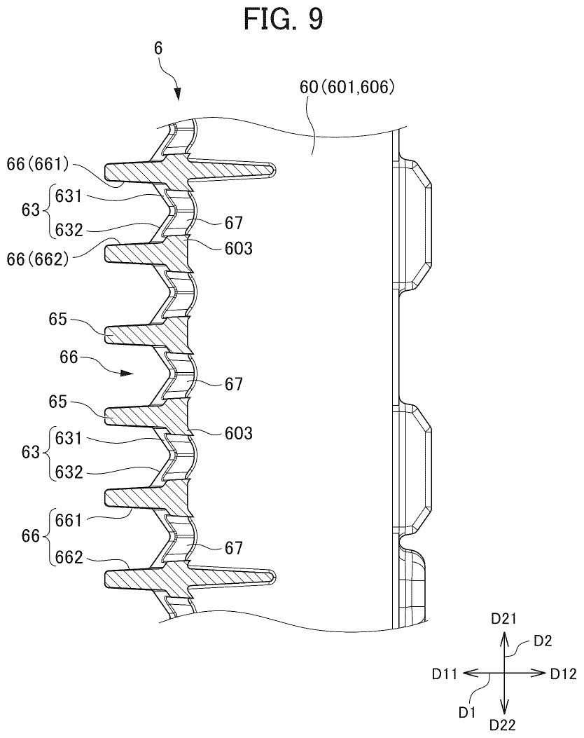

Next, the rear retainer 6 will be described in detail. FIG. 6A is a perspective view illustrating the rear retainer 6 of the substrate storing container 1 according to the embodiment of the present invention. FIG. 6B is a partial front view illustrating the rear retainer 6 of the substrate storing container 1 according to the embodiment of the present invention. FIG. 7A is a partial enlarged view illustrating a periphery of the protruding wall 60 as shown on the left side in FIG. 6A. FIG. 7B is a partial enlarged view illustrating a periphery of the protruding wall 60 as shown on the left side in FIG. 6B. FIG. 7C is a longitudinal cross-sectional view schematically illustrating the back-side substrate support 63 and the substrate edge portion auxiliary portion 65 of the rear retainer 6. FIG. 8 is a partial enlarged view illustrating a periphery of the protruding wall 60 as shown on the left side in FIG. 4. FIG. 9 is a cross-sectional view taken along line A-A in FIG. 6B.

As illustrated in FIGS. 6A to 9, the rear retainer 6 includes the protruding walls 60, the back-side substrate supports 63, the substrate edge portion auxiliary portions 65, an inner frame 62, outer frames 61, and flow holes 67.

Each protruding wall 60 has an outer surface 605 (see FIG. 8) that protrudes toward the container body opening 21 (i.e., toward the front side D11) and an inner surface 606 (see FIG. 8) that bends to be concave toward the container body opening 21. Typically, the inner surface 606 includes a surface that is on a side of the back wall 22 of the container body 2 and a surface that is opposite thereto. The protruding walls 60 are each one-piece wall extending in the upward/downward direction D2. The protruding walls 60 are arranged to form a pair and spaced apart from each other by a predetermined interval in the left/right direction D3. The back-side substrate supports 63 are aligned in twenty-five rows in the upward/downward direction D2 on the protruding side of each protruding wall 60 (i.e., the side close to the front side D11). The back-side substrate supports 63 on the left side D31 and the back-side substrate supports 63 on the right side D32 are arranged to form pairs to be spaced apart from each other by a predetermined interval in the left/right direction D3. Thus, the back-side substrate supports 63, which are arranged to be pairs in the left/right direction D3, are arranged in twenty-five rows in parallel in the upward/downward direction D2.

Each protruding wall 60 includes an outer wall portion 601, an inner wall portion 602, and a front wall portion 603. The outer wall portion 601 forms part of the protruding wall 60 and faces outward in the lateral direction D3. The inner wall portion 602 forms part of the protruding wall 60 and faces inward in the lateral direction D3. The front wall portion 603, which connects the outer wall portion 601 and the inner wall portion 602, forms front-side D11 part of the protruding wall 60. The back-side substrate supports 63 and the substrate edge portion auxiliary portions 65 are provided over substantially the entirety of the front side of the front wall portion 603.

In the present embodiment, each of the outer wall portion 601, the inner wall portion 602, and the front wall portion 603 of the protruding wall 60 is like a plate. However, the shape of the protruding wall 60 may not be limited. For example, the protruding wall 60 may have, in top view, a substantially V-shape from which the front wall portion 603 is substantially absent. The protruding wall 60 may have a curved plate shape instead of a flat plate shape.

The inner frame 62 is a portion that couples and supports the back-side substrate supports 63 on the left side D31 and the back-side substrate supports 63 on the right side D32. The outer frames 61 are respectively integrated with the outer sides in the lateral direction D3 of the protruding walls 60. The rear retainer 6 is fixed (attached) to the container body 2 by engaging the outer frames 61 with the wall 20 of the container body 2.

When the substrates W are stored in the substrate storing space 27 and the lid 3 is closed, the back-side substrate supports 63 hold and support edge ends of the substrates W. As illustrated in FIGS. 7A to 7C, each back-side substrate support 63 has an upper inclined face 631 and a lower inclined face 632.

The upper inclined face 631 is in contact with an edge end of the front side (upper surface) of the substrate W when the container body opening 21 is closed by the lid 3. The lower inclined face 632 is in contact with an edge end of the back side (lower surface) of the substrate W. Specifically, the upper inclined face 631 is constituted of an inclined face that extends toward the center of the substrate storing space 27 in the forward/backward direction D1 as the inclined face extends in the upward direction D21. The lower inclined face 632 is constituted of an inclined face that extends away from the center of the substrate storing space 27 in the forward/backward direction D1 as the inclined face extends in the upward direction D21.

In a state in which the container body opening 21 faces sideways, each back-side substrate support 63 has a V-shaped groove 64 with a lower inclined face 632 disposed lower and an upper inclined face 631 disposed upper. The upper inclined face 631 and the lower inclined face 632 form the V-shaped groove 64, which is concave away from the center of the substrate storing space 27. When the container body opening 21 is closed by the lid 3, an edge end of the front side W1 of the substrate W and an edge end of the back side W2 of the substrate W are in contact with the upper inclined face 631 and the lower inclined face 632, respectively.

The edge end of the back side W2 of the substrate W slides on the lower inclined face 632. When the lid 3 closes the container body opening 21, the substrate W slides on the lower inclined face 632 and rises, and the V-shaped groove 64 supports the edge portion of the substrate W when the substrate W reaches an apex of the V-shaped groove 64. It may be sufficient for the V-shaped groove 64 to be substantially V-shaped in overall view, and the V-shaped groove 64 may additionally have a surface substantially parallel to a D1-D3 plane, a surface substantially parallel to a D2-D3 plane, or the like.

The flow holes 67 penetrate the front wall portion 603 of the protruding wall 60 and the back-side substrate supports 63. Each flow hole 67 is a through hole extending in the forward/backward direction D1. It should be noted that the direction in which the flow holes 67 extend may not be limited. In a case where the substrate storing container 1 is cleaned in a state in which the rear retainer 6 is disposed adjacent to the back wall 22 in the substrate storing space 27 of the container body 2 and subsequently dried in the same state, the container body opening 21 of the container body 2 is generally made to face downward in order to remove liquid (water or the like) present in the substrate storing space 27 of the container body 2. In this case, the protruding sides of the protruding walls 60 of the rear retainer 6 are made to face downward.

In a case where the flow holes 67 are not formed in the protruding walls 60, liquid present on sides of the inner surfaces 606 of the protruding walls 60 remains there (and is difficult to drain from the sides of the inner surfaces 606) even if the protruding sides of the protruding walls 60 of the rear retainer 6 are made to face downward. The flow holes 67 are provided to drain the liquid present on the sides of the inner surfaces 606 of the protruding walls 60 when the protruding sides of the protruding walls 60 are made to face downward. In a state in which the protruding sides of the protruding walls 60 face downward, the flow holes 67 extend in the upward/downward direction D2 to penetrate the back-side substrate supports 63. Therefore, according to the present embodiment, part or all of the liquid existing on the sides of the inner surfaces 606 of the protruding walls 60 is drained through the flow holes 67.

In a case where the flow holes 67 are not formed in the protruding wall 60, an area through which the inner surface 606 and the outer surface 605 of the protruding wall 60 communicate liquidly with each other is relatively small. Accordingly, it is hard for the inner surfaces 606 of the protruding walls 60 to dry. The flow holes 67 are formed to improve breathability (ventilation) by increasing the area where the inner surface 606 and the outer surface 605 of the protruding wall 60 communicate with each other. Due to the flow holes 67, the side of the inner surface 606 of the protruding wall 60 is easily dried in the present embodiment.

In the present embodiment, one back-side substrate support 63 has one flow hole 67. One flow hole 67 has an area of, for example, 30.5 mm² or greater, and may preferably have an area of 30.5 mm² to 40 mm².

Two substrate edge portion auxiliary portions 65 are arranged in pairs to be spaced apart from each other by a predetermined interval in the left/right direction D3. The substrate edge portion auxiliary portions 65 are provided on the front side D11 relative to the back-side substrate supports 63. Similarly to the back-side substrate supports 63, the substrate edge portion auxiliary portions 65, which are disposed in pairs in the left/right direction D3, are arranged such that twenty-five substrate edge portion auxiliary portions 65 are aligned in the upward/downward direction D2.

As illustrated in FIGS. 7A to 9, the back-side substrate supports 63 and the substrate edge portion auxiliary portions 65 are disposed at positions that face the front retainer 7 when the container body opening 21 is closed by the lid 3. The substrate edge portion auxiliary portions 65 define therebetween a plurality of auxiliary grooves 66 each having an opening that is greater than the thickness of the edge portion of a substrate W and allows insertion of the edge portion of the substrate W. Each auxiliary groove 66 is formed of groove forming surfaces including a front-side facing surface 661 and a back-side facing surface 662.

When the container body opening 21 is closed by the lid 3, the edge portion of a substrate W is inserted into an auxiliary groove 66 in a non-contact state in which the edge portion of the substrate W is not in contact with the groove forming surfaces (the front-side facing surface 661 and the back-side facing surface 662) of the auxiliary groove 66 and a space is formed between the edge portion of the substrate W and each of the groove forming surfaces.

When the container body opening 21 is closed by the lid 3, the front-side facing surface 661 is substantially parallel to the front side W1 of the substrate W, and a part of the front-side facing surface 661 faces the front side W1 in the upward/downward direction D2, which is the direction in which the front side W1 and the back side W2 are connected. When the container body opening 21 is closed by the lid 3, the back-side facing surface 662 is substantially parallel to the back side W2 of the substrate W, and a part of the back-side facing surface 662 faces the back side W2 in the upward/downward direction D2, which is the direction in which the front side W1 and the back side W2 are connected.

The front-side facing surface 661 and the back-side facing surface 662 are substantially plane. The front-side facing surface 661 and the back-side facing surface 662 constitute a pair of inclined faces that are slightly inclined so that an opening 664 of the auxiliary groove 66 slightly increases from the bottom (the back side D12) of the auxiliary groove 66 toward the opening 664. An angle θ61 formed between the front side W1 of the substrate W and the front-side facing surface 661 and/or an angle θ62 formed between the back side W2 and the back-side facing surface 662 are/is, for example, 30 degrees or less, and may preferably be 15 degrees or less.

Each auxiliary groove 66 has a depth H66. The edge portions of the substrates W are not inserted into the auxiliary grooves 66 when the container body opening 21 is not closed by the lid 3 and the substrate support plate-like portions 5 serving as the lateral substrate supports support the edge portions of the plurality of substrates W. On the other hand, the edge portions of the substrates W can be inserted into the auxiliary grooves 66 with the depth H66 when the container body opening 21 is closed by the lid 3. The depth H66 of the auxiliary groove 66 is, for example, 8 mm to 10.5 mm, and may preferably be 8 mm to 20 mm. The depth H66 of the auxiliary groove 66 may preferably be greater than the depth H76 of the auxiliary groove 76 of the front retainer 7, and may more preferably be greater than the depth H76 by 14 mm or more.

In a state in which the container body opening 21 faces sideways, the groove forming surfaces 661, 662 of each auxiliary groove 66 are located between the V-shaped grooves 64, 64 of the back-side substrate supports 63 adjacent to each other in the upward/downward direction D2. That is, the arrangement of a groove forming surface (front side-facing surface) 661, a V-shaped groove 64, and a groove forming surface (back-side facing surface) 662 repeats from top to bottom.

A rib 68 that protrudes in the upward direction D21 and extends in a direction from the container body opening 21 toward the back wall 22 of the wall 20 (i.e., in the backward direction D12) is provided on at least an inner side in the lateral direction D3 with respect to a lower inclined face 632 of each back-side substrate support 63. In the present embodiment, a rib 68 is provided over a back-side facing surface 662 of an auxiliary groove 66 between an adjacent pair of substrate edge portion auxiliary portions 65, a lower inclined face 632 of a back-side substrate support 63, and an upper inclined face 631 of the back-side substrate support 63.

The rib 68 protrudes in a direction away from the faces 631 and 632, and includes a first rib portion 681, a second rib portion 682, and a third rib portion 683.

The first rib portion 681 is provided on an inner edge in the lateral direction D3 of the back-side facing surface 662 of an auxiliary groove 66 between the adjacent pair of substrate edge portion auxiliary portions 65. In a state in which the container body opening 21 faces sideways, the first rib portion 681 protrudes in the upward direction D21 and extends in a direction from the container body opening 21 toward the back wall 22 of the wall 20, on the inner side in the lateral direction D3 of the back-side facing surface 662, which is the groove forming surface located on the lower side D22 of the auxiliary groove 66.

The second rib portion 682 is provided on the inner edge portion in the lateral direction D3 of the lower inclined face 632 of the back-side substrate support 63. In the state in which the container body opening 21 faces sideways, the second rib portion 682 protrudes in the upward direction D21 and extends in the direction from the container body opening 21 toward the back wall 22 of the wall 20 on the inner side in the lateral direction D3 of the lower inclined face 632.

The third rib portion 683 is provided on the inner edge portion in the lateral direction D3 of the upper inclined face 631 of the back-side substrate support 63. The first rib portion 681, the second rib portion 682, and the third rib portion 683 are continuous with each other. Providing the first rib portion 681, the second rib portion 682, and the third rib portion 683 reduces the contact area between the substrate W and the substrate edge portion auxiliary portion 65 and the back-side substrate support 63, so that it is possible to reduce the sliding resistance.

As illustrated in FIG. 8, the rear retainer 6 is fixed to the container body 2 with a gap G6 between the rear retainer 6 and the back wall 22 of the wall 20 of the container body 2. In the present embodiment, the back surface (which faces the back wall 22 and is on the back side D12) of the rear retainer 6 is not flat, but has gap forming protrusions 621 that protrude in the backward direction D12. The gap forming protrusions 621 form the gap G6 between the back wall 22 of the container body 2 and a flat portion of the back surface of the rear retainer 6. The size of the gap G6 is, for example, 4 mm or greater, and may preferably be 4 mm to 6 mm. The gap G6 may be formed in any configuration. For example, the gap G6 may alternatively be formed with a protrusion provided on the back wall 22 of the container body 2.

Next, an operation will be described which is performed on the above-described substrate storing container 1 to store the substrates W in the substrate storing space 27 and close the container body opening 21 with the lid 3. First, as illustrated in FIG. 1, the container body 2 is placed such that the forward/backward direction D1 and the left/right direction D3 become parallel to the horizontal plane. Next, a plurality of substrates W are placed on the substrate support plate-like portions 5 and the lower inclined faces 632 of the back-side substrate supports 63. At this time, the substrates W are not positioned in (do not overlap with in plan view) the V-shaped grooves 74 of the lid-side substrate supports 73 or the auxiliary grooves 76 of the substrate edge portion auxiliary portions 75.

Next, the lid 3 is brought close to the container body opening 21 so that the lower inclined faces 732 of the front retainer 7 come into contact with the end edges of the back sides (lower surfaces) of the substrates W, and the upper inclined faces 731 of the front retainer 7 come into contact with the end edges of the front sides of the substrates W. When the lid 3 is further brought close to the container body opening 21, the front portions of the substrates W are pressed in the backward direction D12 by the lower inclined faces 732 and the upper inclined faces 731 of the front retainer 7, and the rear portions of the substrates W are pressed in the forward direction D11 through contacting with the back-side substrate supports 63, whereby the substrates W are held while being pressed in the forward direction D11 and the backward direction D12. A rear portion of each substrate W (on the back side D12) moves in the upward/downward direction D2, while a portion of each substrate W on the opening side (in the forward direction D11) does not move in the upward/downward direction D2. At this time, the substrates W are positioned in (and overlap with in plan view) the auxiliary grooves 76 of the substrate edge portion auxiliary portions 75.

Thereafter, the substrate storing container 1 is rotated by 90 degrees, and then, is conveyed while having the container body opening 21 face vertically upward. Alternatively, without being rotated by 90 degrees, the substrate storing container 1 is conveyed while having the container body opening 21 face horizontally.

When an external impact acts on the substrate storing container 1 during the transport of the substrate storing container 1 having the substrates W stored therein, the substrates W in contact with the V-shaped grooves 74 of the lid-side substrate supports 73 may disengage from the V-shaped grooves 74 by chance. Even in such a case, since the substrates W are not in contact with the auxiliary grooves 76 of the substrate edge portion auxiliary portions 75, the substrates W are less likely to disengage from the auxiliary grooves 76 of the substrate edge portion auxiliary portions 75. Similarly, when an external impact acts on the substrate storing container 1, the substrates W in contact with the V-shaped grooves 64 of the back-side substrate supports 63 may disengage from the V-shaped grooves 64 by chance. Even in such a case, since the substrates W are not in contact with the auxiliary grooves 66 between the substrate edge portion auxiliary portions 65, the substrates W are less likely to disengage from the auxiliary grooves 66 between substrate edge portion auxiliary portions 65. Accordingly, disengagement of the substrates W from the lid-side substrate supports 73 and/or the back-side substrate supports 63 is suppressed, that is, occurrence of cross slotting is suppressed.

The substrate storing container 1 of the embodiment having the above configuration exerts the following effects. The substrate storing container 1 according to the embodiment includes: a container body 2 including a tubular wall 20 that has one end at which a container body opening 21 is formed and another end closed, the container body 2 having a substrate storing space 27 defined by an inner surface of the tubular wall 20, the substrate storing space 27 being capable of storing a plurality of substrates W and communicating with the container body opening 21; a lid 3 detachably attachable to the container body opening 21 and capable of closing the container body opening 21; lid-side substrate supports 73 disposed on a portion of the lid 3, the portion facing the substrate storing space 27 when the container body opening 21 is closed by the lid 3, the lid-side substrate supports 73 being capable of supporting edge portions of the plurality of substrates W when the container body opening 21 is closed by the lid 3; and a rear retainer 6. The rear retainer 6 includes: back-side substrate supports 63 disposed in the substrate storing space 27 so as to form counterparts to the lid-side substrate supports 73 and capable of supporting the edge portions of the plurality of substrates W, the back-side substrate supports 63 being configured to support the plurality of substrates W in collaboration with the lid-side substrate supports 73 such that the edge portions of the plurality of substrates W are arranged in parallel with each other when the container body opening 21 is closed by the lid 3; a protruding wall 60 having an outer surface 605 that protrudes toward the container body opening 21 and an inner surface 606 that is concave toward the container body opening 21, wherein the back-side substrate supports 63 are provided on a protruding side of the protruding wall 60; and flow holes 67 through which liquid and/or gas existing on a side of the inner surface 606 of the protruding wall 60 flows when the protruding side of the protruding wall 60 faces downward.

Due to the above feature, the liquid present on the side of the inner surface 606 of the protruding wall 60 moves through the flow holes 67 in the direction indicated by the arrow DF (see FIG. 8), and is likely to be drained to the side of the outer surface 605 of the protruding wall 60. In addition, the breathability (ventilation) between the side of the inner surface 606 and the side of the outer surface 605 of the protruding wall 60 is high in the direction indicated by the arrow DG (see FIG. 8). Accordingly, in a case where the substrate storing container 1 is cleaned while having the rear retainer 6 disposed adjacent to the back wall 22 in the substrate storing space 27 of the container body 2, the problem of insufficient drying of the inner surface 606 of the rear retainer 6 can be solved or alleviated after the cleaning, thereby eliminating the need to unnecessarily lengthen the drying time and accordingly suppressing an increase in the manufacturing cost.

In a state in which the protruding side of the protruding wall 60 faces downward, the flow holes 67 extend in the upward/downward direction to penetrate the back-side substrate supports 63.

Due to the above feature, the liquid present on the side of the inner surface 606 of the protruding wall 60 moves directly downward to pass smoothly through the flow holes 67, and is quickly drained toward the outer surface 605 of the protruding wall 60.

The rear retainer 6 is fixed to the container body 2 with a gap G6 between the rear retainer 6 and the back wall 22 of the wall 20 of the container body 2.

Due to the above feature, the liquid present between the rear retainer 6 and the back wall 22 of the wall 20 of the container body 2 is less susceptible to the influence of the capillary phenomenon, and easily flows out from between the rear retainer 6 and the back wall 22 of the wall 20 of the container body 2 (and is less likely to remain therebetween).

The space between the rear retainer 6 and the back wall 22 of the wall 20 of the container body 2 is easy to dry.

The back-side substrate supports 63 have V-shaped grooves 64 each of which is formed by a lower inclined face 632 on a lower side D22 and an upper inclined face 631 on an upper side D21 in a state in which the container body opening 21 faces sideways. The lower inclined face 632 has, on its inner side in a lateral direction D3, a second rib portion 682 that protrudes in an upward direction D21 and extends in a direction from the container body opening 21 toward the back wall 22 of the wall 20 in the state in which the container body opening 21 faces sideways.

The above feature makes it possible to reduce a contact surface between the back side W2 of the substrate W and the lower inclined face 632 of the back-side substrate support 63. Therefore, in a process in which the container body opening 21 is closed by the lid 3 and each substrate W slides on the lower inclined face 632 and rises so that an edge portion of the substrate W becomes supported on the V-shaped groove 64, the sliding resistance between the back side W2 of the substrate W and the lower inclined face 632 of the back-side substrate support 63 can be reduced. The second rib portion 682 is disposed on the inner side in the lateral direction D3 of the lower inclined face 632, and is out of alignment with the flow hole 67 in the lateral direction D3. Accordingly, the second rib portion 682 is less likely to inhibit the movement of the liquid that falls through the flow hole 67. In addition, the second rib portion 682 is less likely to reduce the degree of freedom of mold layout for forming the flow holes 67.

The rear retainer 6 further includes auxiliary grooves 66 on a portion that faces the substrate storing space 27 when the container body opening 21 is closed by the lid 3, and the auxiliary grooves 66 each having an opening 664 that is greater than the thickness of the edge portion of the substrate W allow insertion of the edge portion of the substrate W. The auxiliary grooves 66 are each formed by groove forming surfaces (a front-side facing surface 661 and a back-side facing surface 662) that are opposite to each other, and the edge portions of the plurality of substrates W are inserted into the auxiliary grooves 66 on a one-to-one basis at least when the container body opening 21 is closed by the lid 3. When the container body opening 21 is closed by the lid 3, the edge portions of the substrates W are inserted into the auxiliary grooves 66 in a non-contact state in which the edge portion of each substrate W is not in contact with the groove forming surfaces 661, 662 and a space is formed between the edge portion of the substrate W and each of the groove forming surfaces 661, 662. In the state in which the container body opening 21 faces sideways, the groove forming surfaces 661, 662 of each auxiliary groove 66 are located in a V-shaped groove 64 of an adjacent pair of back-side substrate supports 63 adjacent to each other in the upward/downward direction D2.

Due to the above feature, even if an external impact acts on the substrate storing container 1 during the transport of the substrate storing container 1 having the substrates W stored therein, and the substrates W in contact with the back-side substrate supports 63 are likely to disengage from the back-side substrate supports 63 by chance, since the substrates W are not in contact with the auxiliary grooves 66, the substrates W are unlikely to disengage from the auxiliary groove 66. Accordingly, the substrates W can be protected from an impact acting on the substrate storing container 1, and it can be made less likely for the substrates W to disengage from the back-side substrate supports 63, that is, the occurrence of the cross slotting can be suppressed.

The groove forming surface 662 that forms each auxiliary groove 66 and is located on the lower side D22 has, on its inner side in the lateral direction D3, a first rib portion 681 that protrudes in the upward direction D21 and extends in a direction from the container body opening 21 toward the back wall 22 of the wall 20 in the state in which the container body opening 21 faces sideways.

Due to the above feature, a contact area between the back side W2 of the substrate W and the groove forming surface 662 of the auxiliary groove 66 on the lower side D22 can be reduced. Accordingly, in a case where the substrate W slides on the groove forming surface 662 on the lower side D22, the sliding resistance between the back side W2 of the substrate W and the groove forming surface 662 on the lower side D22 can be reduced. The first rib portion 681 is disposed on the inner side in the lateral direction D3 of the groove forming surface 662 on the lower side D22, and is out of alignment with the flow hole 67 in the lateral direction D3. Accordingly, the first rib portion 681 is less likely to inhibit the movement of the liquid falling through the flow hole 67. In addition, the first rib portion 681 is less likely to reduce the degree of freedom of mold layout for forming the flow holes 67.

The present invention is not limited to the above-described embodiments, and may be modified within the technical scope described in the claimed scope.

For example, the shapes of the container body and the lid are not limited to the shapes of the container body 2 and the lid 3 of the above embodiment. The number and dimensions of the substrates W that can be stored in the container body may not be limited to the number and dimensions of the substrates W that can be stored in the container body 2. That is, the configurations of the lateral substrate support (substrate support plate-like portion 5), the front retainer 7, and the rear retainer 6 are not limited to those of the above embodiment. Furthermore, in the above embodiment, the substrate W is a silicon wafer having a diameter of 300 mm, which is merely an exemplary number.

### EXPLANATION OF REFERENCE NUMERALS

1: Substrate storing container

2: Container body

3: Lid

5: Substrate support plate-like portion (lateral substrate support)

6: Rear retainer

21: Container body opening

22: Back wall

27: Substrate storing space

28: Opening peripheral edge

60: Protruding wall

63: Back-side substrate support

64: V-shaped groove

65: Substrate edge portion auxiliary portion

66: Auxiliary groove

67: Flow hole

68: Rib

601: Outer wall portion

602: Inner wall portion

603: Front wall portion

605: Outer surface

606: Inner surface

631: Upper inclined face

632: Lower inclined face

661: Front-side facing surface (groove forming surface)

662: Back-side facing surface (groove forming surface)

664: Opening

681: First rib portion

682: Second rib portion

683: Third rib portion

73: Lid-side substrate support

75: Substrate edge portion auxiliary portion

76: Auxiliary groove

761: Front-side facing surface (groove forming surface)

762: Back-side facing surface (groove forming surface)

D1: Forward/backward direction

D11: Front direction, front side

D12: Backward direction, back side

D2: Upward/downward direction

D21: Upward direction, upper side

D22: Downward direction, lower side

D3: Left/right direction, lateral direction

W: Substrate

1. A substrate storing container comprising:
a container body including a tubular wall that has one end at which a container body opening is formed and another end closed, the container body having a substrate storing space defined by an inner surface of the tubular wall, the substrate storing space being capable of storing a plurality of substrates and communicating with the container body opening;
a lid detachably attachable to the container body opening and capable of closing the container body opening;
lid-side substrate supports disposed on a portion of the lid, the portion facing the substrate storing space when the container body opening is closed by the lid, the lid-side substrate supports being capable of supporting edge portions of the plurality of substrates when the container body opening is closed by the lid; and
a rear retainer, wherein
the rear retainer comprises
back-side substrate supports disposed in the substrate storing space so as to form counterparts to the lid-side substrate supports and capable of supporting edge portions of the plurality of substrates, the back-side substrate supports being configured to support the plurality of substrates in collaboration with the lid-side substrate supports such that the edge portions of the plurality of substrates are arranged in parallel with each other when the container body opening is closed by the lid,
a protruding wall having an outer surface that faces and protrudes toward the container body opening and an inner surface that is opposite the outer surface and concave toward the container body opening, wherein the back-side substrate supports are provided on a protruding side of the protruding wall, and
flow holes through which liquid existing on a side of the inner surface of the protruding wall flows when the protruding side of the protruding wall faces downward.

2. The substrate storing container according to claim 1, wherein
the flow holes extend in an upward/downward direction to penetrate the back-side substrate supports, in a state in which the protruding side of the protruding wall faces downward.

3. The substrate storing container according to claim 1, wherein
the rear retainer is fixed to the container body with a gap between the rear retainer and a back wall of the tubular wall of the container body.

4. The substrate storing container according to claim 1, wherein
the back-side substrate supports have V-shaped grooves each of which is formed of a lower inclined face disposed on a lower side and an upper inclined face disposed on an upper side in a state in which the container body opening faces sideways, and
a rib that protrudes upward and extends in a direction from the container body opening toward the back wall of the tubular wall is provided on a laterally inner side of the lower inclined face, in the state in which the container body opening faces sideways.

5. The substrate storing container according to claim 4, wherein
the rear retainer further includes auxiliary grooves which are disposed on a portion that faces the substrate storing space when the container body opening is closed by the lid, the auxiliary grooves each having an opening that is greater than a thickness of an edge portion of a substrate to allow insertion of the edge portion of the substrate,
the auxiliary grooves are each formed of groove forming surfaces that are opposite to each other and the edge portions of the plurality of substrates are inserted into the auxiliary grooves on a one-to-one basis at least when the container body opening is closed by the lid,
when the container body opening is closed by the lid, the edge portions of the substrates are inserted into the auxiliary grooves in a non-contact state in which an edge portion of each substrate is not in contact with the groove forming surfaces and a space is formed between the edge portion and each of the groove forming surfaces, and
in the state in which the container body opening faces sideways, the groove forming surfaces of each auxiliary groove are located between the V-shaped grooves of the back-side substrate supports adjacent to each other in an upward/downward direction.

6. The substrate storing container according to claim 5, wherein
a rib that protrudes in an upward direction and extends in a direction from the container body opening toward the back wall of the tubular wall is provided on a laterally inner side of a groove forming surface located under an auxiliary groove, in the state in which the container body opening faces sideways.

7. A rear retainer for use in a substrate storing container that includes:
a container body including a tubular wall that has one end at which a container body opening is formed and another end closed, the container body having a substrate storing space defined by an inner surface of the tubular wall, the substrate storing space being capable of storing a plurality of substrates and communicating with the container body opening;
a lid detachably attachable to the container body opening and capable of closing the container body opening; and
lid-side substrate supports disposed on a portion of the lid, the portion facing the substrate storing space when the container body opening is closed by the lid, the lid-side substrate supports being capable of supporting edge portions of the plurality of substrates when the container body opening is closed by the lid,
the rear retainer comprising:
back-side substrate supports disposed in the substrate storing space so as to form counterparts to the lid-side substrate supports and capable of supporting the edge portions of the plurality of substrates, the back-side substrate supports being configured to support the plurality of substrates in collaboration with the lid-side substrate supports such that the edge portions of the plurality of substrates are arranged in parallel with each other when the container body opening is closed by the lid;
a protruding wall having an outer surface that faces and protrudes toward the container body opening and an inner surface that is opposite the outer surface and concave toward the container body opening, wherein the back-side substrate supports are provided on a protruding side of the protruding wall; and
flow holes through which liquid existing on a side of the inner surface of the

8. The rear retainer according to claim 7, wherein
the flow holes extend in an upward/downward direction to penetrate the back-side substrate supports, in a state in which the protruding side of the protruding wall faces downward.

9. The rear retainer according to claim 7, wherein
the rear retainer is fixed to the container body with a gap between the rear retainer and a back wall of the tubular wall of the container body.

10. The rear retainer according to claim 7, wherein
the back-side substrate supports have V-shaped grooves each of which is formed of a lower inclined face disposed on a lower side and an upper inclined face disposed on an upper side in a state in which the container body opening faces sideways, and
a rib that protrudes upward and extends in a direction from the container body opening toward the back wall of the tubular wall is provided on a laterally inner side of the lower inclined face, in the state in which the container body opening faces sideways.

11. The rear retainer according to claim 10, further comprising:
auxiliary grooves which are disposed on a portion that faces the substrate storing space when the container body opening is closed by the lid, the auxiliary grooves each having an opening that is greater than a thickness of an edge portion of a substrate to allow insertion of the edge portion of the substrate, wherein
the auxiliary grooves are each formed of groove forming surfaces that are opposite to each other and the edge portions of the plurality of substrates are inserted into the auxiliary grooves on a one-to-one basis at least when the container body opening is closed by the lid,
when the container body opening is closed by the lid, the edge portions of the substrates are inserted into the auxiliary grooves in a non-contact state in which an edge portion of each substrate is not in contact with the groove forming surfaces and a space is formed between the edge portion and each of the groove forming surfaces, and
in the state in which the container body opening faces sideways, the groove forming surfaces of each auxiliary groove are located between the V-shaped grooves of the back-side substrate supports adjacent to each other in an upward/downward direction.

12. The rear retainer according to claim 11, wherein a rib that protrudes in an upward direction and extends in a direction from the container body opening toward the back wall of the tubular wall is provided on a laterally inner side of a groove forming surface located under an auxiliary groove, in the state in which the container body opening faces sideways.
